(19) United States
(12) Patent Application Publication
(10) Pub. No.: US 2024/0063100 A1
(43) Pub. Date: Feb. 22, 2024

(54) SKIP LAYER WITH AIR GAP ON GLASS SUBSTRATES

(71) Applicant: Intel Corporation, Santa Clara, CA (US)

(72) Inventors: Brandon C. MARIN, Gilbert, AZ (US); Mohammad Mamunur RAHMAN, Gilbert, AZ (US); Jeremy D. ECTON, Gilbert, AZ (US); Gang DUAN, Chandler, AZ (US); Suddhasattwa NAD, Chandler, AZ (US); Srinivas V. PIETAMBARAM, Chandler, AZ (US); Kemal AYGÜN, Tempe, AZ (US); Cemil GEYIK, Gilbert, AZ (US)

(21) Appl. No.: 17/889,229

(22) Filed: Aug. 16, 2022

(51) Int. Cl. H01L 23/498

(52) U.S. Cl. CPC H01L 23/49822; H01L 23/49838; H01L 23/49811

(57) ABSTRACT

Embodiments disclosed herein include electronic packages. In an embodiment, the electronic package comprises a first layer, where the first layer comprises glass, a second layer over the first layer, where the second layer comprises glass, and a third layer over the second layer, where the third layer comprises glass. In an embodiment, a pair of traces are in the second layer, and a first gap is below the pair of traces, where the first gap is in the first layer and the second layer. In an embodiment, a second gap is above the pair of traces, where the second gap is in the second layer and the third layer.

### TECHNICAL FIELD

Embodiments of the present disclosure relate to electronic packages, and more particularly to electronic packages with a glass core that includes skip layer routing with an air gap.

### BACKGROUND

With the advent of high-speed communication, new design concepts such as skip layer architectures have emerged to improve dielectric performance. In a skip layer architecture, traces are built in a middle dielectric layer, and there are one or more dielectric layers that are free from conductive features provided above and below the traces in the middle dielectric layer. Currently buildup film is the material of choice for skip layer designs. However, future serializer/deserializer (SERDES) interface specifications will be more stringent. As such, the use of buildup film for the dielectric material is no longer adequate.

### BRIEF DESCRIPTION OF THE DRAWINGS

FIG. 1A is a cross-sectional illustration of a package substrate with glass layers with serializer/deserializer (SERDES) traces provided in a middle glass layer with air gaps above and below the SERDES traces, in accordance with an embodiment.

FIG. 1B is a cross-sectional illustration of a package substrate with glass layers with SERDES traces that have a tapered cross-section formed with single sided patterning, in accordance with an embodiment.

FIG. 1C is a cross-sectional illustration of a package substrate with glass layers with SERDES traces between air gaps, where the air gaps have a non-planar surface, in accordance with an embodiment.

FIG. 1D is a cross-sectional illustration of a package substrate with glass layers with SERDES traces between air gaps with vias through the glass layers that are slightly misaligned, in accordance with an embodiment.

FIG. 1E is a cross-sectional illustration of a package substrate with glass layers with SERDES traces, where the glass layers have a non-uniform thickness, in accordance with an embodiment.

FIG. 1F is a cross-sectional illustration of a package substrate with glass layers with SERDES traces where the glass layers are bonded to each other using solder interconnects, in accordance with an embodiment.

FIG. 2 is a cross-sectional illustration of an electronic package with a glass core that comprises SERDES traces that are provided below and above air gaps, in accordance with an embodiment.

FIG. 3A is a cross-sectional illustration depicting three glass sublayers that are to be used for a package core, in accordance with an embodiment.

FIG. 3B is a cross-sectional illustration of the three glass layers after vias are formed in the glass layers, in accordance with an embodiment.

FIG. 3C is a cross-sectional illustration of the three glass layers after recesses are formed into the glass layers, in accordance with an embodiment.

FIG. 3D is a cross-sectional illustration of the three glass layers after SERDES traces are formed in the middle glass layer, in accordance with an embodiment.

FIG. 3E is a cross-sectional illustration of the three glass layers after they are bonded to each other in order to form air gaps above and below the SERDES traces, in accordance with an embodiment.

FIG. 4 is a cross-sectional illustration of an electronic system that includes a package substrate with a core that includes SERDES traces with air gaps above and below the SERDES traces, in accordance with an embodiment.

FIG. 5 is a schematic of a computing device built in accordance with an embodiment.

### EMBODIMENTS OF THE PRESENT DISCLOSURE

Described herein are electronic packages with a glass core that includes skip layer routing with an air gap, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, high speed signaling communication architectures, such as serializer/deserializer (SERDES) communication architectures, are limited by dielectric performances of the packaging substrate. In one instance, skip layer architectures can be used in order to improve the electrical performance. In a skip layer architecture, the SERDES traces are provided on a first dielectric layer, and a second dielectric layer above the first dielectric layer and a third dielectric layer below the first dielectric layer are voided (i.e., there is no conductive feature in the second dielectric layer and the third dielectric layer) over the SERDES traces. As such, additional dielectric material is provided around the SERDES traces. However, the dielectric material of typical buildup films does not have relatively low dielectric constants (or relative permeability), and device performance suffers. Additionally, skip layer architectures require more routing layers in the package substrate. This negatively impacts Z-height of the package substrate, and increases the cost of fabricating the package substrate.

Accordingly, embodiments disclosed herein include SERDES routing that is implemented in glass layers of the package substrate. Particularly, the glass layers are patterned in order to provide gaps above and below the SERDES traces. The gaps may be air gaps in some embodiments. Air has a very low dielectric constant (approximately 1.0) and provides better performance than buildup film materials. As such, the electrical performance of the package substrate is improved. In an embodiment, the glass layers may be part of a core of the package substrate. In other embodiments, the package substrate may be entirely glass, and the SERDES structure may be in layers other than the core.

In an embodiment, the package substrate may include a first glass layer, a second glass layer, and a third glass layer. The SERDES traces may be formed in the second glass layer between the first glass layer and the third glass layer. Cavities may be formed in each of the first glass layer, the second glass layer, and the third glass layer. When the glass layers are bonded together, the cavities may align in order to form gaps, such as air gaps, above and below the SERDES traces.

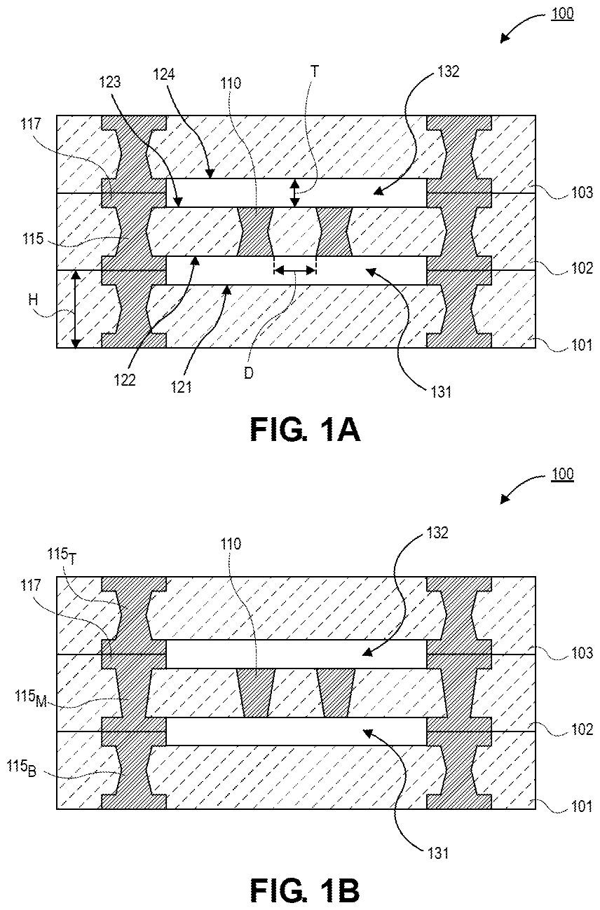

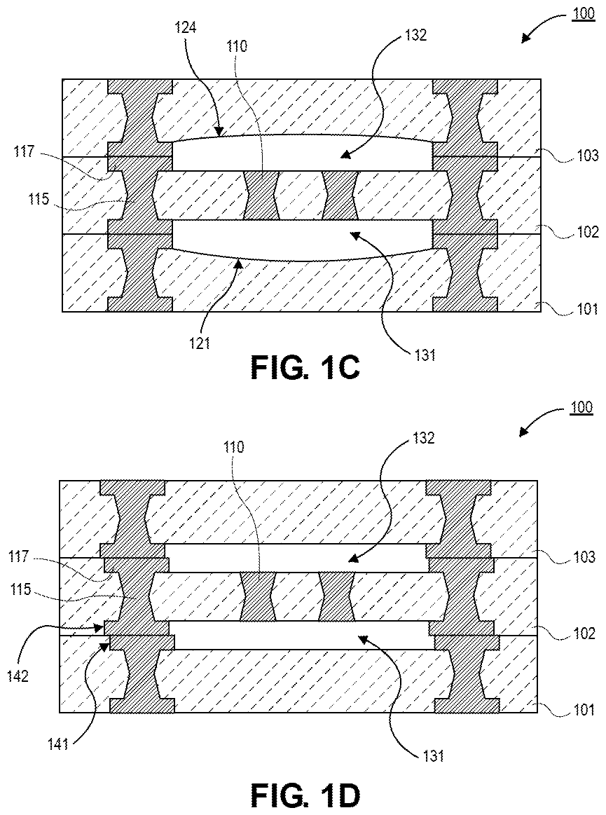

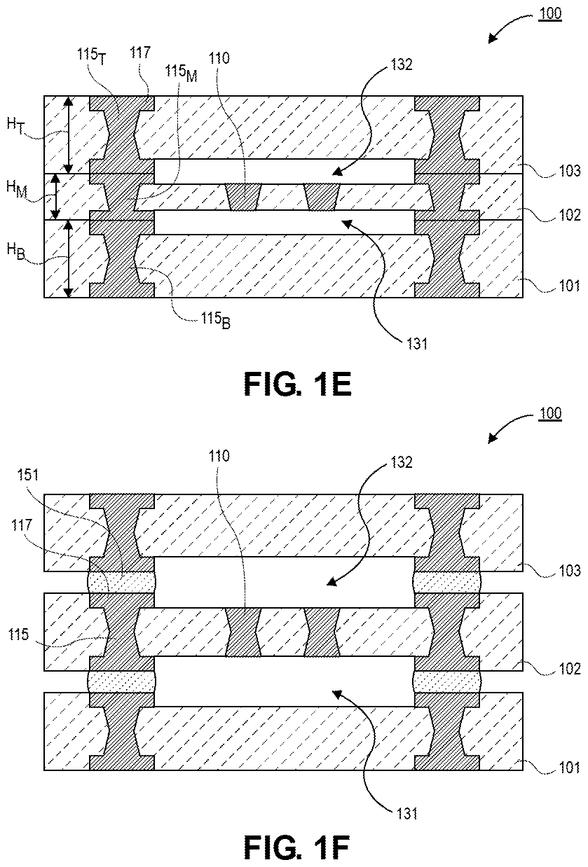

Referring now to FIG. 1A, a cross-sectional illustration of a package substrate 100 is shown, in accordance with an embodiment. In an embodiment, the package substrate 100 may be a core. That is, dielectric buildup layers (not shown) may be provided above and below the package substrate 100 in some embodiments. In a particular embodiment, the package substrate 100 may comprise a plurality of sublayers. The sublayers may comprise glass layers in some embodiments. In an embodiment, the sublayers may include a first layer 101, a second layer 102, and a third layer 103. The layers 101-103 may be bonded to each other (e.g., using any suitable bonding architecture) in order to form the structure of the package substrate 100. In an embodiment, the layers 101-103 may have a thickness H. For example, the thickness H may be between approximately 20 μm and approximately 1,000 μm. Though it is to be appreciated that thinner or thicker thicknesses H may also be used in some embodiments. As used herein, “approximately” refers to a range of values within ten percent of the stated value. For example, approximately 20 μm may refer to a range between 18 μm and 22 μm. In a particular embodiment, the thickness H may be the same for each of the layers 101-103. However, in other embodiments, as will be described in greater detail below, the thickness H may be non-uniform between the layers 101-103.

In an embodiment, the layers 101-103 may be any suitable glass formulation. In a particular embodiment, the glass material may be a glass that is compatible with laser assisted etching processes. For example, the glass may comprise a fused silica glass, a borosilicate glass, or the like. In such embodiments, the glass may be exposed by a laser. The laser exposure may transform a crystal structure or a phase of the material. The transformed structure is more susceptible to an etching chemistry compared to the unexposed regions of the glass.

In an embodiment, vias 115 may be provided through the layers 101-103. The vias 115 may land on pads 117 that are embedded in each layer 101-103. For example, in the second layer 102, a pair of embedded pads 117 (at the top and bottom of the second layer 102) are provided above and below the via 115. The via 115 may have tapered sidewalls. For example, the vias 115 may have an hourglass shaped cross section. An hourglass shaped cross-section may refer to a shape that has a top and a bottom with widths that are greater than a width of the middle of the shape. That is, the width of the via 115 may narrow towards a middle of the via (in the Z-direction). Similar via architectures may also be provided in the first layer 101 and the third layer 103.

In an embodiment, the layers 101-103 may be bonded together with any suitable bonding architecture. For example, a hybrid bonding architecture may be used in some embodiments. In a hybrid bonding architecture, the pads 117 are coupled together with metal-to-metal bonding (e.g., copper-to-copper), and the glass layers 101-103 are bonded together with a glass-to-glass bond. In some instances a seam or the like may be visible between the pads 117 and the glass layers 101-103.

In an embodiment, traces 110 may be provided in the second layer 102. The traces 110 may be a pair of traces 110 (e.g., used for differential signaling). The traces 110 may be SERDES traces in some embodiments. In a particular embodiment, the traces 110 may have an hourglass shaped cross-section. Though, it is to be appreciated that other shapes may also be used, as will be described in greater detail below. In an embodiment, the traces 110 may be spaced from each other by a distance D that is between approximately 20 μm and approximately 100 μm. The traces 110 themselves may have a width that is between approximately 10 μm and approximately 50 μm. The traces 110 may extend into and out of the plane of FIG. 1A.

In an embodiment, gaps 131 and 132 may be provided below and above the traces 110. The gaps 131 and 132 may be air gaps in some embodiments. However, in other embodiments a low dielectric constant material may also be provided in the gaps 131 and 132. In an embodiment, the gap 131 may be defined by a recessed top surface 121 of the first layer 101 and a recessed bottom surface 122 of the second layer 102. The gap 132 may be defined by a recessed top surface 123 of the second layer 102 and a recessed bottom surface 124 of the third layer 103. The out edges of the gaps 131 and 132 may be defined by portions of pads 117 of the via structures. The gaps 131 and 132 may be hermetically sealed in some embodiments. In an embodiment, the gaps 131 and 132 may have a height T that is substantially equal to twice the thickness of the pads 117. In other embodiments, the height T may be between approximately 10 μm and approximately 200 μm.

Referring now to FIG. 1B, a cross-sectional illustration of a package substrate 100 is shown, in accordance with an embodiment. In an embodiment, the package substrate 100 in FIG. 1B may be substantially similar to the electronic package 100 in FIG. 1A, with the exception of the structure of the second layer 102. In an embodiment, the second layer 102 may be fabricated with a single sided laser patterning process. In such an embodiment, the vias 115_{M} may have a tapered structure that is not an hourglass shaped cross-section. That is, the vias 115_{M} may be a different shape than the vias 115E and 115T in the first layer 101 and the third layer 103. Similarly, the traces 110 may have a tapered cross-section that is not an hourglass shaped cross-section. The shapes of the traces 110 and the vias 115_{M} may generally be described as having a trapezoidal shape. In some embodiments, the trapezoidal shape may be possible when a thickness of the second layer 102 is small enough to use a single sided laser exposure and patterning process. In some embodiments, the vias 115T and 115E may also have a trapezoidal cross section as well. That is, the vias 115T, 115B, and 115_{M} may have substantially the same cross-sectional shapes.

Referring now to FIG. 1C, a cross-sectional illustration of an electronic package 100 is shown, in accordance with another embodiment. In an embodiment, the electronic package 100 in FIG. 1C may be substantially similar to the electronic package 100 in FIG. 1A, with the exception of the structure of the gaps 131 and 132. In FIG. 1A, the gaps 131 and 132 have planar surfaces. However, in FIG. 1C, one or more of the surfaces defining the gaps 131 and 132 may have non-planar surfaces. For example, the surface 121 of the first layer 101 and the surface 124 of the third layer 103 may have curved surfaces. The curved surfaces may be the result of the patterning process used to form the recesses. For example, a wet etching process may be used to form the recesses. The wet etching process may result in a non-uniform etch profile that results in a domed or otherwise non-planar surface. The non-planar surfaces may result in gaps 131 and 132 that have a non-uniform height across their length. For example, the height of the gaps 131 and 132 at a center of the gaps 131 and 132 may be greater than a height of the gaps 131 and 132 at edges of the gaps 131 and 132. The recessed surfaces on the second layer 102 may also include non-planar surfaces in some embodiments.

Referring now to FIG. 1D, a cross-sectional illustration of a package substrate 100 is shown, in accordance with an additional embodiment. In an embodiment, the package substrate 100 in FIG. 1D may be substantially similar to the package substrate 100 in FIG. 1A, with the exception of the alignment of the vias 115. In FIG. 1A, the vias 115 are perfectly aligned and illustrate an ideal case. However, as shown in FIG. 1D, the bonding of the glass layers 101-103 may not be perfectly aligned. Accordingly, the vias 115 and pads 117 may be offset from each other. For example, a sidewall 141 of a pad 117 may be offset from a sidewall 142 of an overlying pad 117. In an embodiment, the offset may be approximately 50 nm or greater. In other embodiments, the offset may be approximately 1 μm or greater. In some embodiments, the offset may be up to approximately 5 μm. Offsets between the pads 117 may result in gaps 131 and 132 that have sidewalls that are non-planar. For example, the sidewalls of the gaps 131 and 132 may have stepped profiles, with the width of the step being equal to the offset of the pads 117.

In some embodiments, the offsets between layers may be substantially uniform. That is, the bonding process may have a uniform alignment tolerance. In other embodiments, the offsets between layers may be non-uniform. For example, in FIG. 1D, the offset between the second layer 102 and the third layer 103 may be smaller than an offset between the first layer 101 and the second layer 102.

Referring now to FIG. 1E, a cross-sectional illustration of a package substrate 100 is shown, in accordance with an additional embodiment. In an embodiment, the package substrate 100 in FIG. 1E is substantially similar to the package substrate 100 in FIG. 1A, with the exception of the second layer 102. In an embodiment, the second layer 102 may have a thickness H_{M} that is less than the thicknesses H_{T} and H_{B} of the third layer 103 and the first layer 101. In an embodiment, the thickness H_{T} and H_{B} may be substantially similar to each other. Though, in other embodiments, H_{T} may be different than H_{B}. In an embodiment, the second layer 102 may have a thickness H_{M} that enables the use of single sided patterning of the conductive features. For example, the via 115_{M} may have a trapezoidal shape compared to the hourglass shaped cross-sections of vias 115E and 115T. Similarly, the traces 110 may have trapezoidal cross-sections. The use of a single sided laser exposure process may be simpler and less time consuming than a dual sided laser exposure process. In a particular embodiment, the thickness H_{M} of the layer 102 may be between approximately 10 μm and approximately 100 μm. For example, the thickness H_{M} may be approximately 50 μm or less in some embodiments.

Referring now to FIG. 1F, a cross-sectional illustration of a package substrate 100 is shown, in accordance with an embodiment. In an embodiment, the package substrate 100 in FIG. 1F is substantially similar to the package substrate 100 in FIG. 1A, with the exception of the bonding architecture between the layers 101-103. Instead of a hybrid bonding approach, the layers 101-103 may be bonded to each other with an interconnect 151 or the like. The interconnects 151 may be provided between pads 117 of the layers 101-103. In a particular embodiment, the interconnects 151 may be solder interconnects. The use of interconnects 151 may increase the height of the gaps 131 and 132. The increase in height of the gaps 131 and 132 provides even further improved dielectric properties of the traces 110, and can improve performance overall. However, in some embodiments, the use of interconnects 151 may result in a loss of the hermetically sealed characteristic of the gaps 131 and 132. In the illustrated embodiment, each of the layers 101-103 include substantially similar thicknesses. However, in other embodiments, the layers 101-103 may have non-uniform thicknesses. Additionally, as another benefit, the use of interconnects 151 may provide a self-aligning feature that improves the alignment between the layers 101-103.

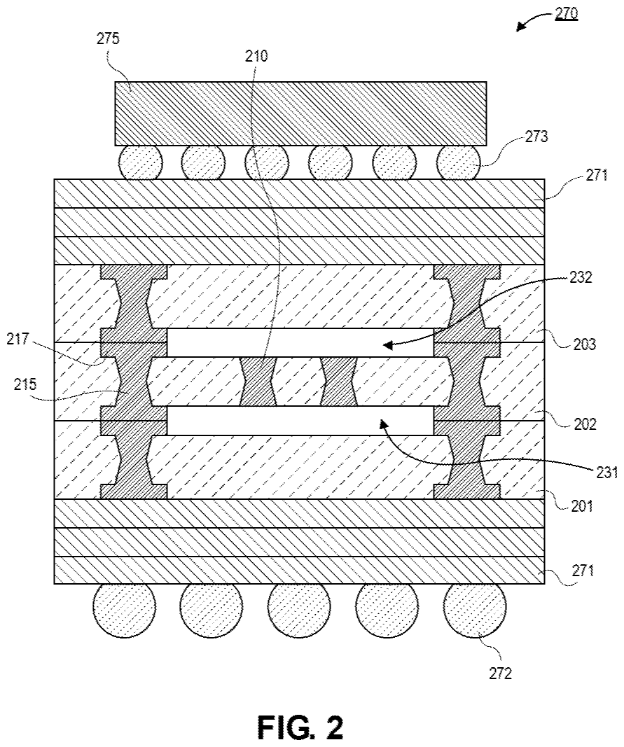

Referring now to FIG. 2, a cross-sectional illustration of an electronic package 270 is shown, in accordance with an embodiment. In an embodiment, the electronic package 270 may comprise a core, such as a glass core. For example, the core may comprise a plurality of glass sublayers, such as layers 201-203. In an embodiment, the layers 201-203 may be bonded to each other using any interconnect architecture described in greater detail above. For example, as shown in FIG. 2, a hybrid bonding process may be used to bond pads 217 and the glass surfaces together. Vias 215 may be provided between the pads 217.

In an embodiment, a pair of traces 210 may be provided in the second layer 202. The traces 210 may be differential signaling traces suitable for use in SERDES architectures. In an embodiment, the traces 210 may have hourglass shaped cross-sections. Though, in other embodiments, the traces 210 may have trapezoidal cross-sections. Trapezoidal cross-sections may be used when the thickness of the second layer 202 is reduced so that single sided patterning may be implemented.

In an embodiment, gaps 231 and 232 may be provided below and above the traces 210. The gaps 231 and 232 may be air gaps, though other materials may also be provided in the gaps 231 and 232. In some instances the gaps 231 and 232 may be hermetically sealed. The gaps 231 and 232 may be defined by recessed surfaces of the glass layers 201-203. For example, each gap 231 or 232 may include a first recess in the second layer 202 and a second recess in either the first layer 201 or the third layer 203. In the illustrated embodiment, the recesses are substantially equal to a height of the pads 217 in the layers 201-203. However, it is to be appreciated that the recesses may be greater than the height of the pads 217 in some embodiments. Additionally, while shown as having substantially planar surfaces, it is to be appreciated that the surfaces defining the gaps 231 and 232 may include non-planar shapes as a result of patterning processes, such as a wet etching process, used to form the recesses. In an embodiment, there may be an absence of conductive features in the glass layers 201 and 203 above and below the gaps 231 and 232.

In an embodiment, the electronic package 270 may further comprise one or more dielectric buildup layers 271 above and below the glass layers 201-203. The buildup layers may be formed with any standard buildup film or the like. The buildup layer 271 may include conductive features (not shown) such as pads, vias, traces, and the like. The conductive routing may provide electrical coupling between conductive features of the core (e.g., traces 210, vias 215, etc.) and the overlying die 275. The die 275 may be coupled to the buildup layers 271 with interconnects 273, such as solder interconnects or any other first level interconnect (FLI) architecture. In an embodiment, interconnects 272 may be provided at the bottom of the electronic package 270. The interconnects 272 may be solder balls, sockets, or the like. The interconnects 272 may provide coupling to a board (not shown).

In an embodiment, the glass layers 201-203 are shown as being the core of the electronic package 270. However, in other embodiments, the glass layers 201-203 may be provided above or below the core. For example, in an all glass substrate, the glass layers 201-203 may be any of the layers in the structure.

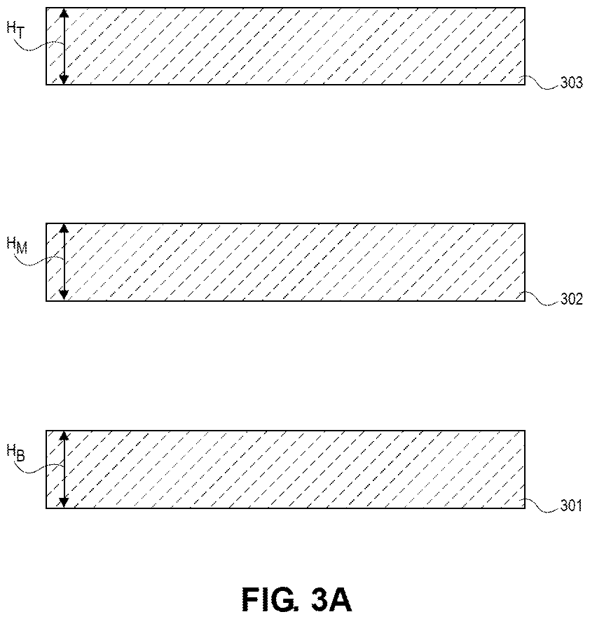

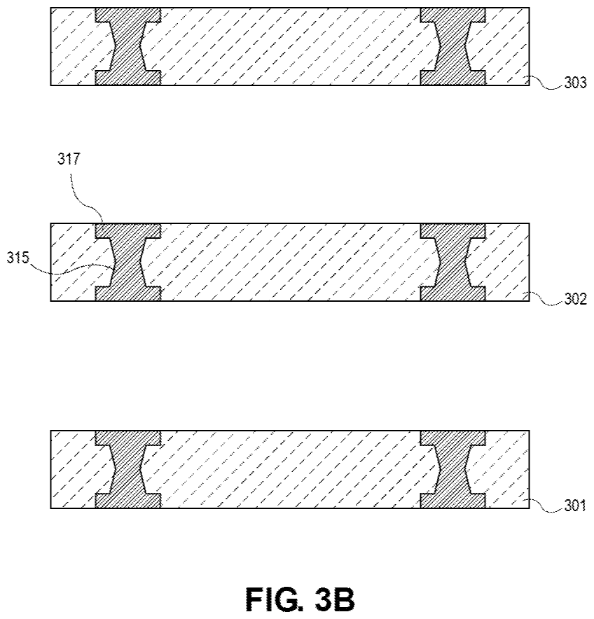

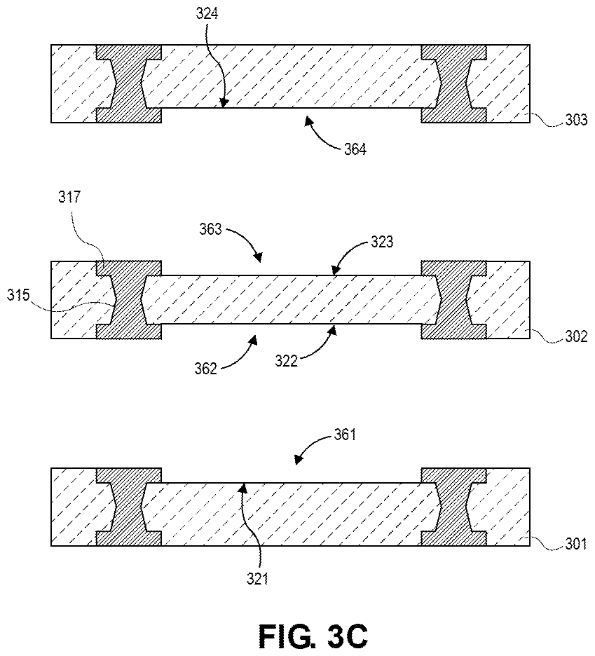

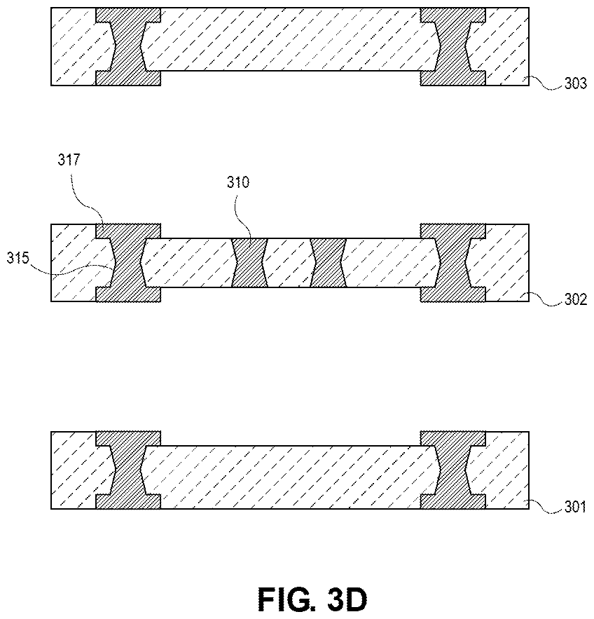

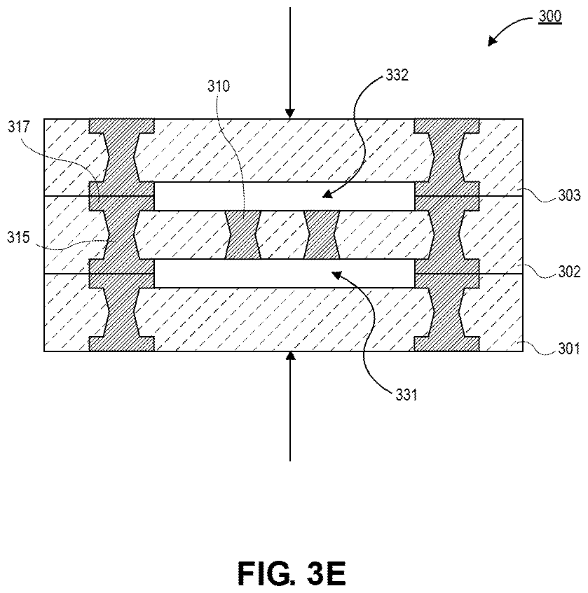

Referring now to FIGS. 3A-3E, a series of cross-sectional illustrations depicting a process for fabricating a package substrate is shown, in accordance with an embodiment. In FIGS. 3A-3D a set of three layers 301, 302, and 303 are shown. It is to be appreciated that the three layers 301, 302, and 303 may be fabricated substantially in parallel, with the three layers 301, 302, and 303 being bonded together in FIG. 3E. While shown as being fabricated at the same time, the layers 301, 302, and 303 may be fabricated at any time, and once all three layers 301-303 are completed, they are bonded together, as shown in FIG. 3E.

Referring now to FIG. 3A, a cross-sectional illustration of a first layer 301, a second layer 302, and a third layer 303 is shown, in accordance with an embodiment. In an embodiment, the first layer 301, the second layer 302, and the third layer 303 may each be glass layers. In an embodiment, the thicknesses H_{B}, H_{M}, and H_{T} may be substantially similar to each other. Though, in other embodiments the thicknesses H_{B}, H_{M}, and H_{T} may be different from each other. For example, H_{M} may be smaller than H_{B} and H_{T}. In an embodiment, the layers 301-303 may include a glass material that is suitable for laser assisted patterning. That is, the layers 301-303 may include a glass material that, upon laser exposure, changes microstructure or phase in order to be more susceptible to an etching process compared to the unexposed regions.

Referring now to FIG. 3B, a cross-sectional illustration of the layers 301-303 after patterning is shown, in accordance with an embodiment. In an embodiment, the layers 301-303 may be patterned with a laser assisted patterning process. After via openings are formed, the via openings may be filled with a conductive material (e.g., copper) using a suitable plating process to form vias 315 and pads 317. In an embodiment, the vias 315 may have any suitable cross-section. In a particular embodiment shown in FIG. 3B, the cross-section may be an hourglass shaped cross-section. Such a shape is formed when dual sided patterning is implemented. In embodiments with layers 301-303 that are thin enough, a single sided patterning may be used to form vias 315 that have trapezoidal cross-sections. The pads 317 may also be embedded in the layers 301-303, as opposed to being formed on top or bottom surfaces of the layers 301-303.

Referring now to FIG. 3C, a cross-sectional illustration of the layers 301-303 after recesses are formed is shown, in accordance with an embodiment. In an embodiment, the first layer 301 may include a recess 361. The recess 361 may be to a depth substantially equal to a thickness of the pad 317. The recess 361 may result in the formation of a recessed surface 321 on the top of the first layer 301. The recessed surface 321 may be planar, as shown in FIG. 3C. In other embodiments, the recessed surface 321 may be non-planar (e.g., curved or domed) due to an etching process used to form the recess 361.

In an embodiment, the second layer 302 may have two recesses formed 362 and 363. The recess 362 results in a recessed surface 322, and the recess 363 results in a recessed surface 323. The recesses may be formed with an etching process or the like. While shown as being substantially planar, it is to be appreciated that the surfaces 322 and 323 may be curved, domed, or otherwise non-planar in some embodiments.

In an embodiment, the third layer 303 may include a recess 364. The recess 364 results in a recessed surface 324. In an embodiment, the recess 364 may be formed with an etching process or the like. In some embodiments, the recessed surface 324 may be curved, domed, or otherwise non-planar.

In the illustrated embodiments, the recesses 361-364 are formed to a depth that is substantially equal to the height of the pads 317 on each layer. However, it is to be appreciated that the recesses 361-364 may be formed to any desired depth. Increasing the depth of the recesses 361-364 results in wider gaps, which may provide improved electrical performance of the completed core.

Referring now to FIG. 3D, a cross-sectional illustration of the layers 301-303 is shown, in accordance with an embodiment. As shown, the second layer 302 may be patterned in order to form traces 310. In an embodiment, the traces 310 may be formed with a laser assisted patterning process. The traces 310 may have hourglass shaped cross-sections when a dual sided patterning process is used. In other embodiments with a single sided patterning process, the traces 310 may have trapezoidal cross-sections.

Referring now to FIG. 3E, a cross-sectional illustration of the layers 301-303 after they are bonded together to form a package substrate 300 is shown, in accordance with an embodiment. The layers 301-303 may be bonded together with a hybrid bonding process. The hybrid bonding process results in pads 317 being bonded together as well as the glass layers 301-303 being bonded together. In an embodiment, seams may be visible at the bonding interfaces. In an embodiment, the bonding process may result in the formation of gaps 331 and 332 below and above the traces 310. The gaps 331 and 332 may be hermetically sealed in some embodiments.

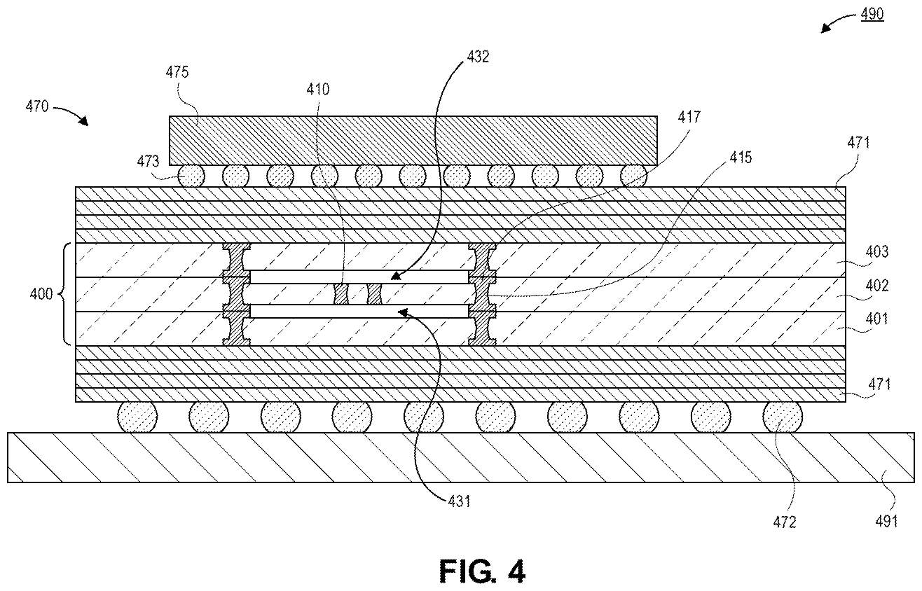

Referring now to FIG. 4, a cross-sectional illustration of an electronic system 490 is shown, in accordance with an embodiment. In an embodiment, the electronic system 490 may include a board 491, such as a printed circuit board (PCB). In an embodiment, the electronic package 470 is coupled to the board 491 by interconnects 472, such as solder interconnects or the like. In an embodiment, the electronic package 470 comprises a core 400. The core 400 may include multiple glass layers 401-403. Traces 410 may be provided in the second glass layer 401 between air gaps 431 and 432. Vias 415 and pads 417 may be provided adjacent to the air gaps 431 in some embodiments. In an embodiment, dielectric buildup layers 471 may be provided above and below the core 400. In an embodiment, a die 475 may be coupled to the top buildup layers 471 by interconnects 473, such as an FLI architecture.

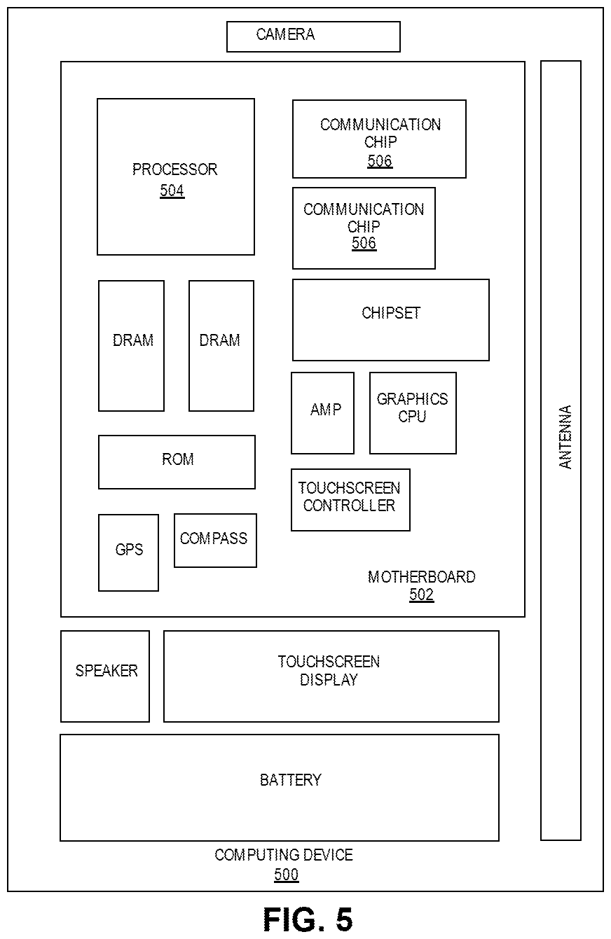

FIG. 5 illustrates a computing device 500 in accordance with one implementation of the invention. The computing device 500 houses a board 502. The board 502 may include a number of components, including but not limited to a processor 504 and at least one communication chip 506. The processor 504 is physically and electrically coupled to the board 502. In some implementations the at least one communication chip 506 is also physically and electrically coupled to the board 502. In further implementations, the communication chip 506 is part of the processor 504.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 506 enables wireless communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 506 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 500 may include a plurality of communication chips 506. For instance, a first communication chip 506 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 504 of the computing device 500 includes an integrated circuit die packaged within the processor 504. In some implementations of the invention, the integrated circuit die of the processor may be part of an electronic system that includes a glass core with SERDES traces between air gaps, in accordance with embodiments described herein. The term “processor” may refer to any device or portion of a device that processes electronic data from registers and/or memory to transform that electronic data into other electronic data that may be stored in registers and/or memory.

The communication chip 506 also includes an integrated circuit die packaged within the communication chip 506. In accordance with another implementation of the invention, the integrated circuit die of the communication chip may be part of an electronic system that includes a glass core with SERDES traces between air gaps, in accordance with embodiments described herein.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an electronic package, comprising: a first layer, wherein the first layer comprises glass; a second layer over the first layer, wherein the second layer comprises glass; a third layer over the second layer, wherein the third layer comprises glass; a pair of traces in the second layer; a first gap below the pair of traces, wherein the first gap is in the first layer and the second layer; and a second gap above the pair of traces, wherein the second gap is in the second layer and the third layer.

Example 2: the electronic package of Example 1, wherein the first gap and the second gap are air gaps.

Example 3: the electronic package of Example 1 or Example 2, wherein the pair of traces have tapered sidewalls.

Example 4: the electronic package of Example 3, wherein the pair of traces have hourglass shaped cross-sections.

Example 5: the electronic package of Examples 1-4, wherein vias are formed through the first layer, the second layer, and the third layer, wherein the vias are adjacent to the first gap and the second gap.

Example 6: the electronic package of Example 5, wherein the vias have one or more misaligned edges with each other.

Example 7: the electronic package of Example 5 or Example 6, wherein the first layer is bonded to the second layer with a hybrid bonding architecture, and wherein the second layer is bonded to the third layer with a hybrid bonding architecture.

Example 8: the electronic package of Examples 1-7, wherein the first gap and the second gap are hermetically sealed.

Example 9: the electronic package of Examples 1-8, wherein a thickness of the first layer and the third layer is greater than a thickness of the second layer.

Example 10: the electronic package of Examples 1-9, wherein the first gap and the second gap comprise non-planar surfaces.

Example 11: the electronic package of Example 1, wherein the first layer, the second layer, and the third layer comprise fused silica glass or borosilicate glass.

Example 12: the electronic package of Examples 1-11, wherein the first layer is bonded to the second layer with solder, and wherein the second layer is bonded to the third layer with solder.

Example 13: an electronic package, comprising: a glass core; a first trace in the glass core; a second trace in the glass core, wherein the second trace is laterally adjacent to the first trace; and a gap above and below the first trace and the second trace.

Example 14: the electronic package of Example 13, wherein the glass core comprises three or more glass sublayers.

Example 15: the electronic package of Example 14, wherein the first trace and the second trace are in a middle glass sublayer of the three or more glass sublayers.

Example 16: the electronic package of Example 14 or Example 15, wherein a seam is provided between each of the glass sublayers.

Example 17: the electronic package of Examples 13-16, wherein the gap comprises a first non-linear surface and a second non-linear surface.

Example 18: the electronic package of Examples 13-17, wherein vias are provided through the glass core adjacent to the first trace and the second trace.

Example 19: the electronic package of Examples 13-18, wherein the first trace and the second trace have tapered edges.

Example 20: the electronic package of Example 19, wherein the first trace and the second trace have hourglass shaped cross-sections.

Example 21: the electronic package of Examples 13-20, further comprising: organic buildup layers above and below the glass core.

Example 22: the electronic package of Examples 13-21, wherein the gap has a height up to approximately 200 μm both above and below the first trace and the second trace.

Example 23: an electronic system, comprising: a board; an electronic package coupled to the board, wherein the electronic package comprises: a glass core; serializer/deserializer (SERDES) traces in the glass core; a first air gap above the SERDES traces; and a second air gap below the SERDES traces; and a die coupled to the electronic package.

Example 24: the electronic system of Example 23, wherein the glass core comprises three sublayers.

Example 25: the electronic system of Example 24, wherein the SERDES traces are provided in a middle sublayer of the three sublayers.

What is claimed is:

1. An electronic package, comprising:
a first layer, wherein the first layer comprises glass;
a second layer over the first layer, wherein the second layer comprises glass;
a third layer over the second layer, wherein the third layer comprises glass;
a pair of traces in the second layer;
a first gap below the pair of traces, wherein the first gap is in the first layer and the second layer; and
a second gap above the pair of traces, wherein the second gap is in the second layer and the third layer.

2. The electronic package of claim 1, wherein the first gap and the second gap are air gaps.

3. The electronic package of claim 1, wherein the pair of traces have tapered sidewalls.

4. The electronic package of claim 3, wherein the pair of traces have hourglass shaped cross-sections.

5. The electronic package of claim 1, wherein vias are formed through the first layer, the second layer, and the third layer, wherein the vias are adjacent to the first gap and the second gap.

6. The electronic package of claim 5, wherein the vias have one or more misaligned edges with each other.

7. The electronic package of claim 5, wherein the first layer is bonded to the second layer with a hybrid bonding architecture, and wherein the second layer is bonded to the third layer with a hybrid bonding architecture.

8. The electronic package of claim 1, wherein the first gap and the second gap are hermetically sealed.

9. The electronic package of claim 1, wherein a thickness of the first layer and the third layer is greater than a thickness of the second layer.

10. The electronic package of claim 1, wherein the first gap and the second gap comprise non-planar surfaces.

11. The electronic package of claim 1, wherein the first layer, the second layer, and the third layer comprise fused silica glass or borosilicate glass.

12. The electronic package of claim 1, wherein the first layer is bonded to the second layer with solder, and wherein the second layer is bonded to the third layer with solder.

13. An electronic package, comprising:
a glass core;
a first trace in the glass core;
a second trace in the glass core, wherein the second trace is laterally adjacent to the first trace; and
a gap above and below the first trace and the second trace.

14. The electronic package of claim 13, wherein the glass core comprises three or more glass sublayers.

15. The electronic package of claim 14, wherein the first trace and the second trace are in a middle glass sublayer of the three or more glass sublayers.

16. The electronic package of claim 14, wherein a seam is provided between each of the glass sublayers.

17. The electronic package of claim 13, wherein the gap comprises a first non-linear surface and a second non-linear surface.

18. The electronic package of claim 13, wherein vias are provided through the glass core adjacent to the first trace and the second trace.

19. The electronic package of claim 13, wherein the first trace and the second trace have tapered edges.

20. The electronic package of claim 19, wherein the first trace and the second trace have hourglass shaped cross-sections.

21. The electronic package of claim 13, further comprising:
organic buildup layers above and below the glass core.

22. The electronic package of claim 13, wherein the gap has a height up to approximately 200 μm both above and below the first trace and the second trace.

23. An electronic system, comprising:
a board;
an electronic package coupled to the board, wherein the electronic package comprises:
a glass core;
serializer/deserializer (SERDES) traces in the glass core;
a first air gap above the SERDES traces; and
a second air gap below the SERDES traces; and
a die coupled to the electronic package.

24. The electronic system of claim 23, wherein the glass core comprises three sublayers.

25. The electronic system of claim 24, wherein the SERDES traces are provided in a middle sublayer of the three sublayers.
